(19) United States
(12) Patent Application Publication
(10) Pub. No.: US 2026/0268473 A1
(43) Pub. Date: Sep. 10, 2026

(54) PATTERN MATCHING METHOD

(71) Applicant: TASMIT, INC., Kanagawa (JP)

(72) Inventor: Yuji MIURA, Kanagawa (JP)

(21) Appl. No.: 18/876,894

(22) PCT Filed: Jun. 16, 2023
(86) PCT No.: PCT/JP2023/022449

§ 371 Date: Dec. 19, 2024

(30) Foreign Application Priority Data
Jun. 29, 2022 (JP) 2022-104405

(51) Int. Cl. G06T 7/00; G06V 10/75; G06V 20/69

(52) U.S. Cl. CPC G06T 7/001; G06V 10/751; G06V 20/698; G06T 2207/10061; G06T 2207/30136; G06T 2207/30164

(57) ABSTRACT

A pattern matching method includes: calculating pattern densities in inspection areas (A1 to A10) from design data; dividing the pattern densities into density groups (PG1 to PG3) according to numerical values of the pattern densities; generating images of the inspection areas by a scanning electron microscope (1); performing pattern matching between a pattern on each of the images and a corresponding CAD pattern; calculating image shift amounts corresponding to the inspection areas (A1 to A10) based on results of the pattern matching; dividing the inspection areas (A1 to A10) into area groups (AG1 to AG3) corresponding to the density groups (PG1 to PG3); calculating correction amounts (C1 to C3) corresponding to the area groups (AG1 to AG3).

### TECHNICAL FIELD

The present invention relates to a method of pattern matching between a pattern on an image of a workpiece, such as a wafer or glass substrate, and a CAD pattern created from design data of the pattern, and in particular to a technology for reducing an effect of image shift caused by charging of a surface of the workpiece on the pattern matching.

### BACKGROUND ART

A die-to-database method is a pattern matching method for matching between a pattern on an image of a workpiece (e.g., a wafer or a glass substrate) having the pattern formed thereon and a CAD pattern created from design data of the pattern. More specifically, the die-to-database method includes: obtaining coordinates of an area to be inspected from the design data; moving a stage on which the workpiece is placed to the coordinates; generating an SEM image of the pattern on the workpiece by irradiating the workpiece with an electron beam; overlaying the SEM image on the CAD pattern created from the design data; creating a gray-level profile of the SEM image within a range starting from an edge of the CAD pattern; determining an edge of the pattern on the SEM image from the gray level profile; and determining a matching position that minimizes a bias value between the determined edge position and the corresponding edge of the CAD pattern.

During the image generation in the die-to-database method, the electron beam may be bent due to an effect of charged surface of the workpiece. As a result, an imaging target position and an actual imaging position may be different. FIG. 10 is a schematic diagram showing an example of positional shift between a CAD pattern and a pattern on an SEM image. When positional shift between a CAD pattern 501 and a pattern 502 on an SEM image is large, matching between the CAD pattern 501 and the pattern 502 on the SEM image may fail. Therefore, a shift amount of the SEM image is obtained from a shift amount when the CAD pattern 501 and the pattern 502 on the SEM image are matched, and a position of the stage is moved by the shift amount of the SEM image at the time of the next image generation, thereby minimizing a difference between the imaging target position and the actual imaging position. In another method, when the effect of charging is expected to be large, the matching search range is set large in advance to prevent failure of pattern matching.

### CITATION LIST

### Patent Literature

Patent document 1: Japanese laid-open patent publication No. H05-324836

### SUMMARY OF INVENTION

### Technical Problem

In high-density and simple patterns, such as those in a memory cell, the charge is uniform over the workpiece surface, and the effect of the charge is not large. Therefore, the pattern on the SEM image and the CAD pattern can be correctly matched by the correction of the conventional technology. However, in a workpiece with a large difference in pattern density, such as a logic device, the effect of the charge can be large locally.

FIG. 11 is a schematic diagram showing a charged surface of a workpiece having high pattern density, and FIG. 12 is a schematic diagram showing a charged surface of a workpiece having a low pattern density. A patterned surface 601 of the workpiece is constituted of an insulating layer 603 (e.g., an interlayer insulating layer) made of an insulating material, and interconnects 605 made of metal, such as copper. When an image of the patterned surface 601 is generated, the patterned surface 601 is irradiated with an electron beam, and as a result, charging of the insulating layer 603 occurs. As can be seen from a comparison between FIG. 11 and FIG. 12, in the patterned surface 601 with a low pattern density, an exposed area of the insulating layer 603 is large and an amount of charging is large.

In this way, large electrostatic charges occur locally within the patterned surface 601. In the conventional technology described above, the actual imaging position may be significantly shifted from the imaging target position, resulting in a failure in the matching. If the range for searching for the matching position is widened in order to avoid this, an error in determining the matching position may occur. Moreover, a time required to search for an appropriate matching position may increase, resulting in a decrease in throughput.

Therefore, the present invention provides a technique for reducing an effect of non-uniform charging of a surface of a workpiece on pattern matching.

### Solution to Problem

In an embodiment, there is provided a matching method comprising: setting a plurality of inspection areas in a patterned surface of a workpiece; calculating pattern densities in the plurality of inspection areas from design data of patterns of the workpiece; dividing the pattern densities into a plurality of density groups according to numerical values of the pattern densities; generating images of the plurality of inspection areas by a scanning electron microscope; performing pattern matching between a pattern on each of the images and a corresponding CAD pattern; calculating a plurality of image shift amounts corresponding to the plurality of inspection areas based on results of the pattern matching; dividing the plurality of inspection areas into a plurality of area groups corresponding to the plurality of density groups; calculating a plurality of correction amounts corresponding to the plurality of area groups based on the image shift amounts corresponding to the inspection areas belonging to the respective area groups; and generating correlation data indicating correlation between the plurality of density groups and the plurality of correction amounts.

In an embodiment, the pattern matching method further comprises: calculating a pattern density of a target inspection area on an inspection-target workpiece from design data of pattern in the target inspection area, the inspection-target workpiece having a patterned surface of the same structure as the patterned surface of the workpiece; selecting a density group to which the pattern density of the target inspection area belongs from the plurality of density groups; correcting a matching-search distance using a correction amount corresponding to the selected density group; generating an image of the target inspection area by scanning electron microscope; and performing pattern matching between a pattern on the image of the target inspection area and a corresponding CAD pattern using the corrected matching-search distance.

In an embodiment, correcting the matching-search distance comprises correcting the matching-search distance by adding a correction amount corresponding to the selected density group to a reference search distance.

In an embodiment, calculating the plurality of correction amounts corresponding to the plurality of area groups comprises: calculating an average and 3σ of image shift amounts corresponding to inspection area belonging to each of the area groups; and calculating a correction amount that is the sum of the average and the 3σ for each of the area groups, thereby determining the plurality of correction amounts corresponding to the plurality of area groups.

In an embodiment, there is provided a pattern matching method comprising: setting a plurality of inspection areas in a patterned surface of a workpiece; calculating pattern densities in the plurality of inspection areas from design data of patterns of the workpiece; dividing the pattern densities into a plurality of density groups according to numerical values of the pattern densities; generating images of the plurality of inspection areas by a scanning electron microscope; performing pattern matching between a pattern on each of the images and a corresponding CAD pattern; calculating a plurality of X-direction image shift amounts and a plurality of Y-direction image shift amounts corresponding to the plurality of inspection areas based on results of the pattern matching; dividing the plurality of inspection areas into a plurality of area groups corresponding to the plurality of density groups; calculating a plurality of X-direction correction amounts corresponding to the plurality of area groups based on the plurality of X-direction image shift amounts corresponding to the inspection areas belonging to the respective area groups; calculating a plurality of Y-direction correction amounts corresponding to the plurality of area groups based on the plurality of Y-direction image shift amounts corresponding to the inspection areas belonging to the respective area groups; generating X-direction correlation data indicating correlation between the plurality of density groups and the plurality of X-direction correction amounts; and generating Y-direction correlation data indicating correlation between the plurality of density groups and the plurality of Y-direction correction amounts.

In an embodiment, the pattern matching method further comprises: calculating a pattern density of a target inspection area on an inspection-target workpiece from design data of pattern in the target inspection area, the inspection-target workpiece having a patterned surface of the same structure as the patterned surface of the workpiece; selecting a density group to which the pattern density of the target inspection area belongs from the plurality of density groups; determining a X-direction correction amount and a Y-direction correction amount corresponding to the selected density group; correcting a position of a workpiece stage of scanning electron microscope by moving the workpiece stage by the determined X-direction correction amount in an X direction and moving the workpiece stage by the determined Y-direction correction amount in a Y direction, the inspection-target workpiece being supported on the workpiece stage; generating an image of the target inspection area of the inspection-target workpiece on the workpiece stage by the scanning electron microscope; and performing pattern matching between a pattern on the image of the target inspection area and a corresponding CAD pattern.

In an embodiment, calculating the plurality of X-direction correction amounts corresponding to the plurality of area groups comprises: calculating an average and 3σ of X-direction image shift amounts corresponding to inspection area belonging to each of the area groups; and calculating an X-direction correction amount that is the sum of the average and the 3σ of the X-direction image shift amounts for each of the area groups, thereby determining the plurality of X-direction correction amounts corresponding to the plurality of area groups.

In an embodiment, calculating the plurality of Y-direction correction amounts corresponding to the plurality of area groups comprises: calculating an average and 3σ of Y-direction image shift amounts corresponding to inspection area belonging to each of the area groups; and calculating a Y-direction correction amount that is the sum of the average and the 3σ of the Y-direction image shift amounts for each of the area groups, thereby determining the plurality of Y-direction correction amounts corresponding to the plurality of area groups.

### Advantageous Effects of Invention

Based on the relationship between the pattern density of the target inspection area obtained from the design data of the pattern and the statistical image shift amount of the SEM image caused by charging, a correction amount according to the pattern density of the target inspection area is determined. Furthermore, the correction of the matching-search distance and/or the correction of the stage position according to the pattern density can improve the accuracy of pattern matching, so that the pattern matching can be completed in a minimum matching search time.

### BRIEF DESCRIPTION OF DRAWINGS

FIG. 1 is a schematic diagram showing one embodiment of an image generation system;

FIG. 2 is a schematic diagram showing an example of a plurality of inspection areas;

FIG. 3 is a graph showing an example of a plurality of inspection areas and pattern densities of these inspection areas;

FIG. 4 is a graph showing an example of a plurality of inspection areas and image shift amounts corresponding to these inspection areas;

FIG. 5 is a graph in which a graph of the pattern densities shown in FIG. 3 is superimposed on a graph of the image shift amounts shown in FIG. 4;

FIG. 6 is a flowchart for explaining one embodiment for calculating a correction amount of a matching-search distance;

FIG. 7 is a flowchart for explaining an embodiment in which pattern matching is performed using the correction amount of the matching-search distance;

FIG. 8 is a flowchart for explaining an embodiment of calculating a correction amount of a position of a workpiece stage;

FIG. 9 is a flowchart for explaining an embodiment of performing pattern matching using an X-direction correction amount and a Y-direction correction amount for the workpiece stage;

FIG. 10 is a schematic diagram showing an example of positional shift between a CAD pattern and a pattern on an SEM image;

FIG. 11 is a schematic diagram showing charging of a workpiece surface having a high pattern density; and

FIG. 12 is a schematic diagram showing charging of a workpiece surface having a low pattern density.

### DESCRIPTION OF EMBODIMENTS

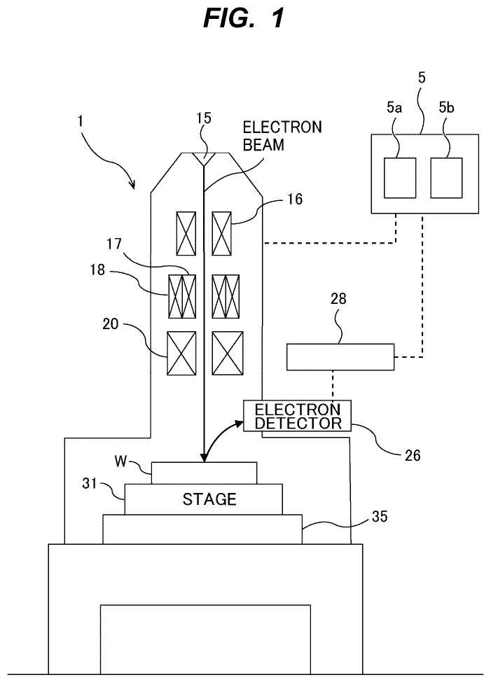

Hereinafter, embodiments of the present invention will be described with reference to the drawings. FIG. 1 is a schematic diagram showing an embodiment of an image generation system. The image generation system includes a scanning electron microscope 1 configured to generate an image of a workpiece W, and a processing system 5 configured to process the image generated by the scanning electron microscope 1. Examples of the workpiece W include wafer, mask, panel, and substrate used in manufacturing of semiconductor devices.

The processing system 5 is composed of at least one computer. The processing system 5 includes a memory 5a storing programs therein, and an arithmetic device 5b configured to execute arithmetic operations according to instructions included in the programs. The memory 5a includes a main memory, such as a random access memory (RAM), and an auxiliary memory, such as a hard disk drive (HDD) or a solid state drive (SSD). Examples of the arithmetic device 5b include a CPU (Central Processing Unit) and a GPU (Graphics Processing Unit). However, specific configuration of the processing system 5 is not limited to this embodiment.

The processing system 5 may be an edge server coupled to the scanning electron microscope 1 by a communication line, or may be a cloud server coupled to the scanning electron microscope 1 by a communication network, such as the Internet or a local network, or may be a fog computing device (gateway, fog server, router, etc.) installed in a network coupled to the scanning electron microscope 1. The processing system 5 may be a combination of multiple servers. For example, the processing system 5 may be a combination of an edge server and a cloud server coupled to each other by a communication network, such as the Internet or a local network. In another example, the processing system 5 may include multiple servers (computers) that are not coupled by a network.

The scanning electron microscope 1 has an electron gun 15 configured to emit an electron beam, a converging lens 16 configured to converge the electron beam emitted from the electron gun 15, an X deflector 17 configured to deflect the electron beam in an X direction, a Y deflector 18 configured to deflect the electron beam in a Y direction, an objective lens 20 configured to focus the electron beam on the workpiece W which is an example of a specimen, a workpiece stage 31 configured to support the workpiece W, and a stage-moving device 35 configured to translate the workpiece stage 31. A configuration of the electron gun 15 is not particularly limited. For example, a field-emitter type electron gun, a semiconductor-photocathode type electron gun, etc. can be used as the electron gun 15.

The electron beam emitted from the electron gun 15 is converged by the converging lens 16, and then deflected by the X deflector 17 and the Y deflector 18 while being focused by the objective lens 20 on a surface of the workpiece W. When the workpiece W is irradiated with primary electrons of the electron beam, electrons, such as secondary electrons and backscattered electrons, are emitted from the workpiece W. The electrons emitted from the workpiece W are detected by an electron detector 26. Electron detection signals from the electron detector 26 are input to an image acquisition device 28 and converted into an image. In this manner, the scanning electron microscope 1 generates an image of the surface of the workpiece W. The image acquisition device 28 is coupled to the processing system 5.

The stage-moving device 35 is configured to move the workpiece stage 31 in a direction parallel to the surface of the workpiece W. More specifically, the stage-moving device 35 is configured to move the workpiece stage 31 in the X direction and the Y direction perpendicular to the X direction. The X direction and the Y direction are both horizontal directions parallel to the surface of the workpiece W. The operation of the stage-moving device 35 is controlled by the processing system 5.

Next, an embodiment of a pattern matching method performed by the image generation system will be described. The processing system 5 sets a plurality of inspection areas within a patterned surface (a surface on which patterns are formed) of the workpiece W. Size and shape of each inspection area are not particularly limited. In one example, each inspection area may be an area equivalent to the field of view (FOV) of the scanning electron microscope 1, or may be multiple areas within the field of view (FOV) of the scanning electron microscope 1.

The processing system 5 calculates a pattern density in each of the plurality of inspection areas from design data of the patterns on the workpiece W. The patterns on the workpiece W are created according to the design data (which may be called CAD data). CAD is an abbreviation for computer-aided design. The design data is pre-stored in the memory 5a of the processing system 5. The pattern density is defined as a ratio of a total area of the pattern in the inspection area to a total area of the inspection area.

$$Pattern density ( \% ) = total area of pattern in inspection area / total area of inspection area \times 100$$

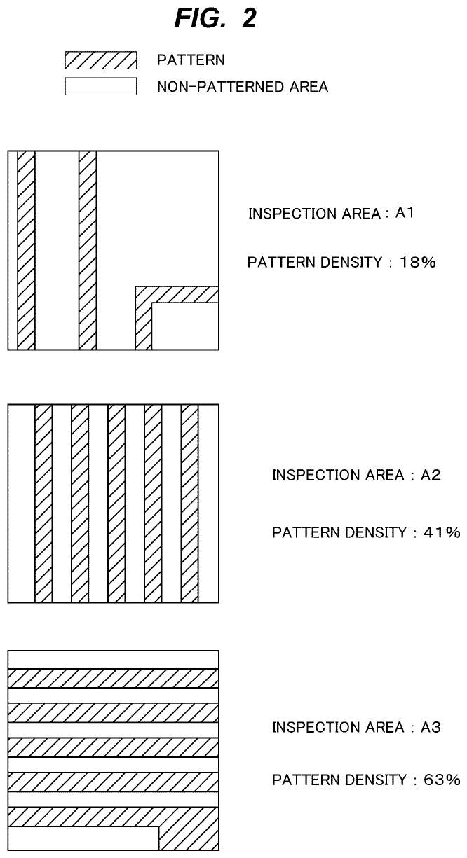

FIG. 2 is a schematic diagram showing an example of inspection areas. In inspection areas A1, A2, and A3, there are patterns and non-patterned areas. The patterns are made of metal, and the non-patterned areas are made of insulating material. Shape and area of the pattern typically vary from inspection area to inspection area. Therefore, the pattern density also differs from inspection area to inspection area. Although three inspection areas A1, A2, and A3 are shown in FIG. 2, more inspection areas may be set in the patterned surface of one workpiece W.

The processing system 5 divides the respective pattern densities of the inspection areas into a plurality of density groups according to numerical values of the pattern densities. In this embodiment, the pattern densities are classified using a plurality of threshold values. For example, the processing system 5 divides the pattern densities into a first density group smaller than a first threshold value, a second density group between the first threshold value and a second threshold value (the first threshold value<the second threshold value), and a third density group larger than the second threshold value. The threshold values can be a plurality of discrete values in a range from 0% to 100%, or continuous values in a range from 0% to 100%.

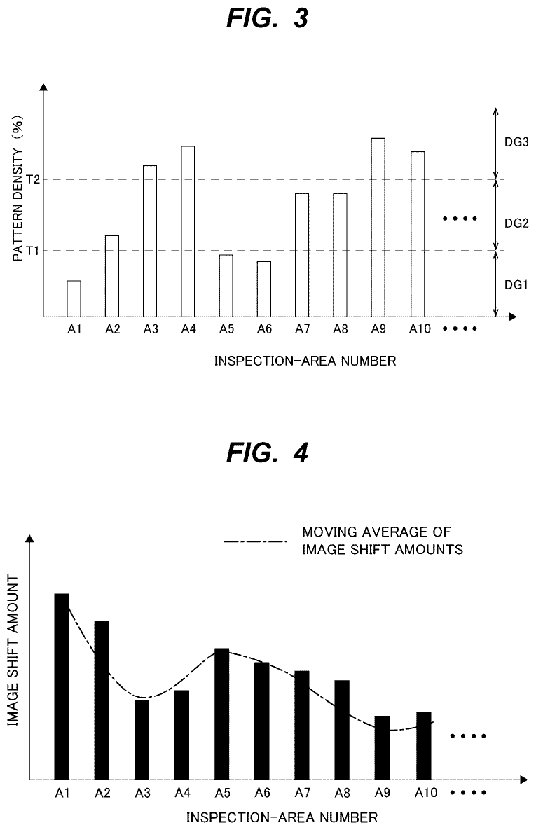

FIG. 3 is a graph showing an example of inspection areas and pattern densities of these inspection areas. In FIG. 3, vertical axis represents the pattern density (%), and horizontal axis represents inspection-area number. In the example shown in FIG. 3, the pattern densities are divided into three density groups DG1, DG2, and DG3 by a first threshold value T1 and a second threshold value T2 (T1<T2).

Next, the processing system 5 instructs the scanning electron microscope 1 to generate an image of each of the multiple inspection areas. Multiple images of the multiple inspection areas are stored in the memory 5a of the processing system 5.

The processing system 5 performs pattern matching between a pattern on each image and a corresponding CAD pattern. The CAD pattern is a virtual pattern created by the processing system 5 based on pattern-design information contained in the design data of patterns formed on the patterned surface of the workpiece W. The pattern matching is performed according to the die-to-database method.

The processing system 5 calculates a plurality of image shift amounts corresponding to the plurality of inspection areas, respectively, based on results of the pattern matching. Each image shift amount is expressed as a vector amount of deviation between a pattern on an image and a corresponding CAD pattern. Specifically, the image shift amount is expressed as a square root of the sum of squares of a shift amount in the X direction, which is an X component of the vector, and a shift amount in the Y direction, which is a Y component of the vector. Depending on the shape of the pattern, the image shift amount may be expressed as the shift amount in the X direction or the shift amount in the Y direction.

FIG. 4 is a graph showing an example of inspection areas and image shift amounts corresponding to these inspection areas, respectively. In FIG. 4, vertical axis represents the image shift amount, and horizontal axis represents inspection-area number. The processing system 5 may calculate moving averages of the image shift amounts along an arrangement direction of the inspection areas. In one embodiment, the image shift amounts may be the moving averages of the image shift amounts.

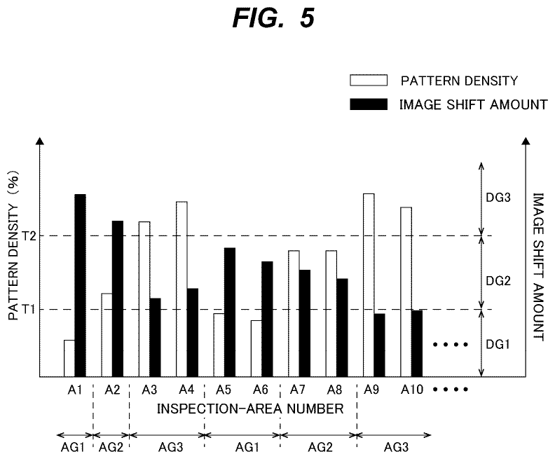

FIG. 5 is a graph in which the graph of the pattern densities shown in FIG. 3 is superimposed on the graph of the image shift amounts shown in FIG. 4. In FIG. 5, vertical axis on the right side represents the image shift amount, vertical axis on the left side represents the pattern density, and horizontal axis represents inspection-area number. In the example shown in FIG. 5, the processing system 5 divides the plurality of inspection areas into a plurality of area groups AG1, AG2, and AG3 corresponding to the plurality of density groups DG1, DG2, and DG3. In the example shown in FIG. 5, the inspection areas A1, A5, and A6 belonging to the density group DG1 are classified into the area group AG1, the inspection areas A2, A7, and A8 belonging to the density group DG2 are classified into the area group AG2, and the inspection areas A3, A4, A9, and A10 belonging to the density group DG3 are classified into the area group AG3.

The processing system 5 calculates a plurality of correction amounts corresponding to the plurality of area groups, respectively, based on the image shift amounts corresponding to the inspection areas belonging to the respective area groups. In the example shown in FIG. 5, the processing system 5 calculates a correction amount C1 corresponding to the area group AG1, based on the image shift amounts corresponding to the inspection areas A1, A5, and A6 belonging to the area group AG1. The image shift amount may be a moving average along the arrangement direction of the inspection areas. The correction amount C1 may be a value obtained by adding 3σ to an average Av₁ of the image shift amounts corresponding to the inspection areas A1, A5, and A6 (i.e., C1=Av₁+3σ). The symbol o represents a standard deviation.

Similarly, the processing system 5 calculates a correction amount C2 (i.e., C2=Av₂+3σ) corresponding to the area group AG2 based on the image shift amounts corresponding to the inspection areas A2, A7, and A8 belonging to the area group AG2, and calculates a correction amount C3 (i.e., C3=Av₃+3σ) corresponding to the area group AG3 based on the image shift amounts corresponding to the inspection areas A3, A4, A9, and A10 belonging to the area group AG3.

In this manner, the correction amounts C1, C2, and C3 are determined for the area groups AG1, AG2, and AG3, respectively. As can be seen from FIG. 5, the area groups AG1, AG2, and AG3 correspond to the density groups DG1, DG2, and DG3. Therefore, the correction amounts C1, C2, and C3 correspond to the density groups DG1, DG2, and DG3, respectively. The processing system 5 generates correlation data indicating correlation between the density groups DG1, DG2, and DG3 and the correction amounts C1, C2, and C3, and stores the correlation data in the memory 5a. The correlation data may be a table indicating the correlation between the density groups and the correction amounts, or may be a relational expression indicating the correlation between the density groups and the correction amounts.

Next, an embodiment of performing the matching pattern using the correction amounts C1, C2, and C3 determined as described above will be described.

The processing system 5 calculates a pattern density of a target inspection area on an inspection-target workpiece from design data of a pattern in the target inspection area. The design data of the pattern in the target inspection area is stored in advance in the memory 5a of the processing system 5.

The inspection-target workpiece is a workpiece having a patterned surface of the same structure as the patterned surface of the workpiece W that has been used to generate the correlation data indicating the correlation between the density groups DG1, DG2, DG3 and the correction amounts C1, C2, C3. For example, if the patterned surface of the workpiece W used to generate the correlation data has a gate structure, the patterned surface of the inspection-target workpiece also has a gate structure. The workpiece W and the inspection-target workpiece have the same surface structure and the same surface material. In this specification, “same” means not only completely the same, but also substantially the same in light of common technical knowledge.

The processing system 5 selects a density group to which the pattern density of the target inspection area belongs from the plurality of density groups DG1, DG2, and DG3. Furthermore, the processing system 5 corrects a matching-search distance using a correction amount corresponding to the selected density group. For example, when the density group DG2 is selected as the density group to which the pattern density of the target inspection area belongs, the processing system 5 corrects the matching-search distance using the correction amount C2 corresponding to the density group DG2.

The matching-search distance is a distance (or range) from an edge of a CAD pattern created from the design data of the pattern in the target inspection area. An edge of a pattern on the image is searched within this matching-search distance. According to the embodiment, the matching-search distance is corrected according to the pattern density of the target inspection area. The pattern density affects an amount of charging. Therefore, in other words, the matching-search distance is corrected according to the amount of charging of the target inspection area.

In one embodiment, the processing system 5 corrects the matching-search distance by adding the correction amount corresponding to the selected density group to a reference search distance. An example of the reference search distance is half a maximum pitch of the pattern in the target inspection area. The half the maximum pitch of the pattern is a minimum distance (range) at which the pattern matching can be successful. In one example, if the selected density group is DG2, the correction amount is C2, and the maximum pitch of the pattern in the target inspection area is PT, the corrected matching-search distance is expressed as PT/2+C2.

The processing system 5 instructs the scanning electron microscope 1 to generate the image of the target inspection area, acquires the image of the target inspection area from the scanning electron microscope 1, and performs the pattern matching between the pattern on the image of the target inspection area and the corresponding CAD pattern using the corrected matching-search distance. The processing system 5 searches for an edge on the image within the corrected matching-search distance, so that the pattern matching can be performed with high accuracy and in a minimum search time.

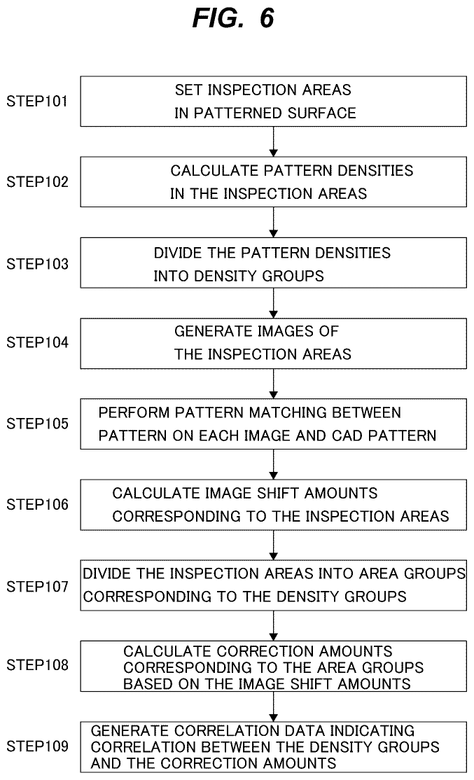

FIG. 6 is a flow chart for explaining one embodiment of calculating the above-mentioned correction amount for the matching-search distance.

In step 101, the processing system 5 sets a plurality of inspection areas within the patterned surface of the workpiece W. The number of inspection areas is not particularly limited, and 100 or more inspection areas may be set.

In step 102, the processing system 5 calculates respective pattern densities in the plurality of inspection areas set in the step 101 from the design data of the patterns on the workpiece W.

In step 103, the processing system 5 divides the pattern densities calculated in the step 102 into a plurality of density groups according to numerical values of the pattern densities. Specifically, the processing system 5 divides the plurality of pattern densities into a plurality of density groups using a plurality of threshold values.

In step 104, the processing system 5 instructs the scanning electron microscope 1 to generate images of the plurality of inspection areas set in the step 101.

In step 105, the processing system 5 performs the pattern matching between a pattern on each image of the plurality of inspection areas and a corresponding CAD pattern. The pattern matching can be performed according to a known method.

In step 106, the processing system 5 calculates a plurality of image shift amounts corresponding to the plurality of multiple inspection areas based on results of the pattern matching.

In step 107, the processing system 5 divides the plurality of inspection areas into a plurality of area groups corresponding to the plurality of density groups set in the step 103 (see FIG. 5).

In step 108, the processing system 5 calculates a plurality of correction amounts corresponding to the plurality of area groups, respectively, based on the plurality of image shift amounts corresponding to the plurality of inspection areas belonging to the respective area groups. More specifically, the processing system 5 calculates an average and 3σ of image shift amounts in each area group, and calculates a correction amount for each area group that is the sum of the average and 3σ. The image shift amount may be a moving average of the image shift amounts along the arrangement direction of the inspection areas.

In step 109, the processing system 5 generates the correlation data indicating the correlation between the plurality of density groups and the plurality of correction amounts, and stores the correlation data in the memory 5a.

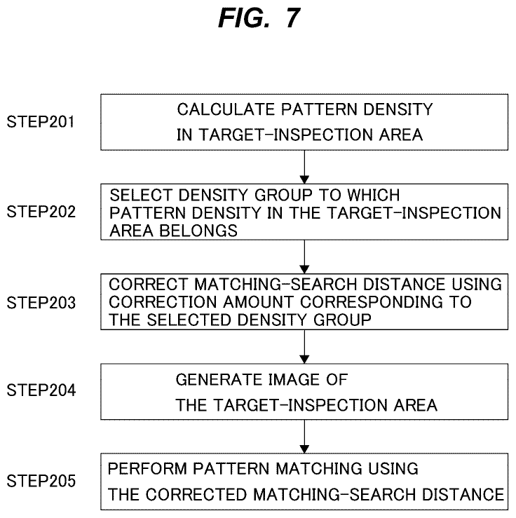

FIG. 7 is a flowchart to explain one embodiment of performing the pattern matching using the correction amount for the matching-search distance.

In step 201, the processing system 5 calculates a pattern density of a target inspection area on an inspection-target workpiece from design data of pattern in the target inspection area. The inspection-target workpiece has a patterned surface of the same structure as the patterned surface of workpiece W.

In step 202, the processing system 5 selects a density group to which the pattern density of the target inspection area belongs from the plurality of density groups determined in the step 103.

In step 203, the processing system 5 corrects the matching-search distance using a correction amount corresponding to the density group selected in the step 202. The correction amount corresponding to the selected density group is uniquely determined from the correlation data generated in the step 109.

In step 204, the processing system 5 instructs the scanning electron microscope 1 to generate an image of the target inspection area.

In step 205, the processing system 5 acquires the image of the target inspection area from the scanning electron microscope 1, and performs the pattern matching between the pattern on the image of the target inspection area and the corresponding CAD pattern using the matching-search distance corrected in the step 203.

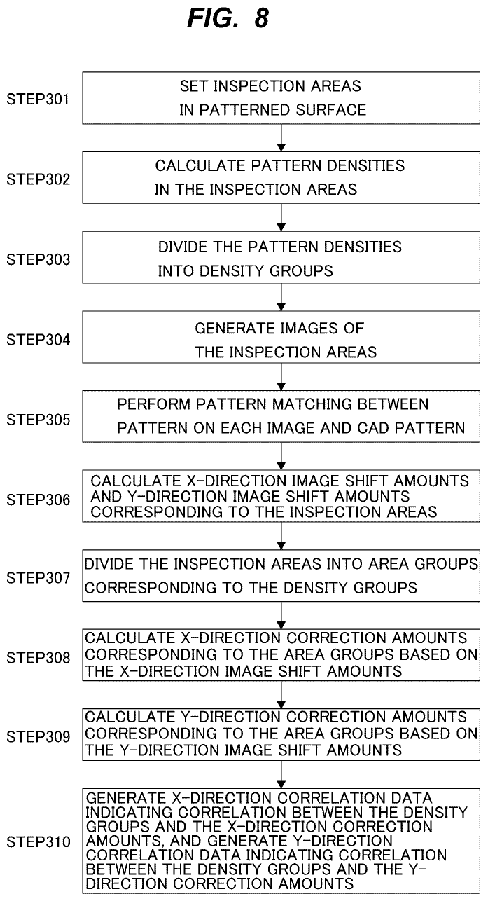

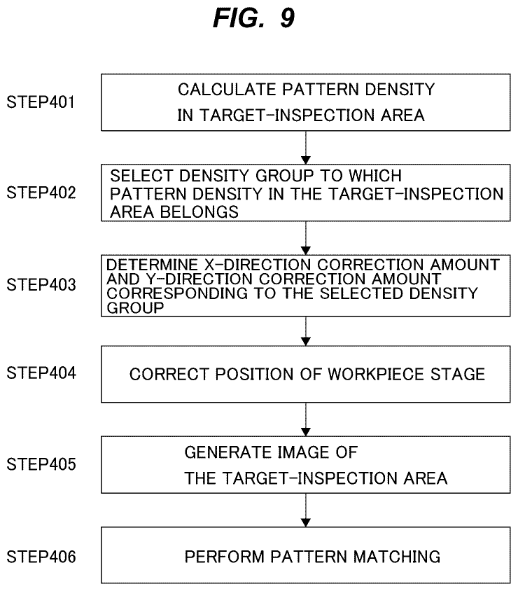

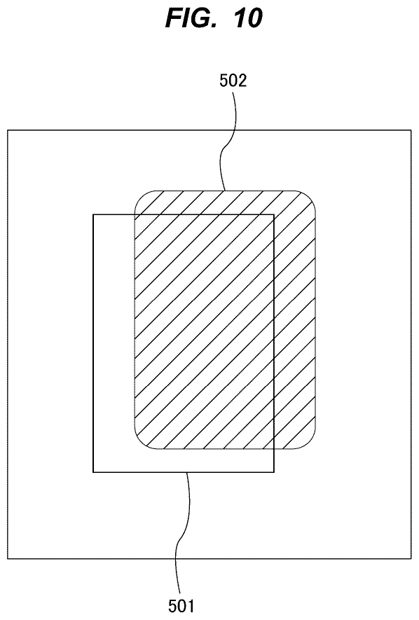

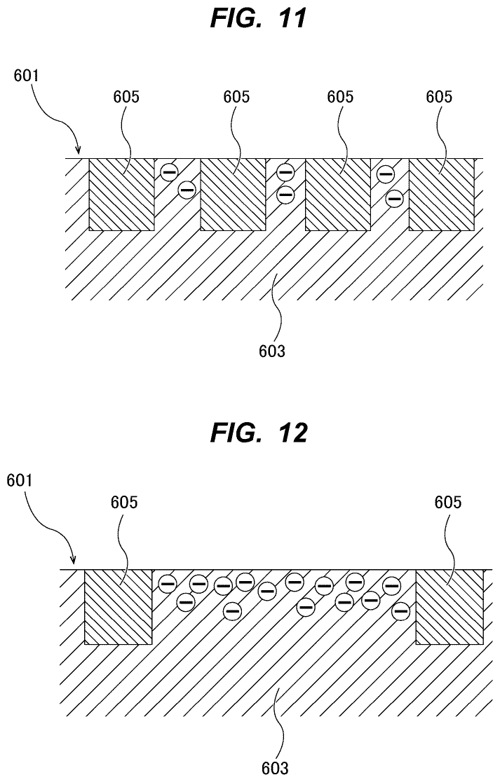

Next, another embodiment of pattern matching will be described with reference to FIGS. 8 and 9. In this embodiment, the processing system 5 corrects a position of the workpiece stage 31 shown in FIG. 1 instead of correcting the matching-search distance, thereby reducing the image shift itself of the target inspection area. Configuration and operation of this embodiment that are not particularly described are the same as those of the above embodiments described with reference to FIGS. 1 to 7, and duplicated description will be omitted.

FIG. 8 is a flow chart for explaining one embodiment of calculating a correction amount for the position of the workpiece stage 31. Steps 301 to 305 in FIG. 8 are the same as the steps 101 to 105 in FIG. 6, and repetitive explanations will be omitted.

In step 306, the processing system 5 calculates a plurality of X-direction image shift amounts and a plurality of Y-direction image shift amounts corresponding to the plurality of inspection areas, respectively, based on the result of the pattern matching in the step 305. The X-direction image shift amount is an image shift amount in the X direction, and the Y-direction image shift amount is an image shift amount in the Y direction perpendicular to the X direction.

In step 307, the processing system 5 divides the plurality of inspection areas into a plurality of area groups corresponding to the plurality of density groups set in the step 303 (see FIG. 5).

In step 308, the processing system 5 calculates a plurality of X-direction correction amounts corresponding to the plurality of area groups, respectively, based on the plurality of X-direction image shift amounts corresponding to the plurality of inspection areas belonging to the respective area groups. More specifically, the processing system 5 calculates an average and 3σ of X-direction image shift amounts in each area group, and calculates an X-direction correction amount that is the sum of the average and 3σ of the X-direction image shift amounts for each area group, thereby determining the plurality of X-direction correction amounts corresponding to the plurality of area groups, respectively. The X-direction image shift amount may be a moving average of the X-direction image shift amounts along the arrangement direction of the inspection areas.

In step 309, the processing system 5 calculates a plurality of Y-direction correction amounts corresponding to the plurality of area groups, respectively, based on the plurality of Y-direction image shift amounts corresponding to the plurality of inspection areas belonging to the respective area groups. More specifically, the processing system 5 calculates an average and 3σ of Y-direction image shift amounts in each area group, and calculates a Y-direction correction amount that is the sum of the average and 3σ of the Y-direction image shift amounts for each area group, thereby determining the plurality of Y-direction correction amounts corresponding to the plurality of area groups, respectively. The Y-direction image shift amount may be a moving average of the Y-direction image shift amounts along the arrangement direction of the inspection areas.

The step 308 may be performed after the step 309 or may be performed simultaneously with the step 309.

In step 310, the processing system 5 generates X-direction correlation data indicating correlation between the plurality of density groups and the plurality of X-direction correction amounts, generates Y-direction correlation data indicating correlation between the plurality of density groups and the plurality of Y-direction correction amounts, and stores the X-direction correlation data and the Y-direction correlation data in the memory 5a.

FIG. 9 is a flowchart to explain one embodiment of performing the pattern matching using X-direction correction amount and Y-direction correction amount for the workpiece stage 31.

In step 401, the processing system 5 calculates a pattern density of a target inspection area on an inspection-target workpiece from design data of pattern in the target inspection area. The inspection-target workpiece has a patterned surface of the same structure as the patterned surface of the workpiece W.

In step 402, the processing system 5 selects a density group to which the pattern density of the target inspection area belongs from the plurality of density groups determined in the step 303.

In step 403, the processing system 5 determines an X-direction correction amount and a Y-direction correction amount corresponding to the density group selected in the step 402. The X-direction correction amount is uniquely determined from the X-direction correlation data, and the Y-direction correction amount is uniquely determined from the Y-direction correlation data.

In step 404, the processing system 5 instructs the scanning electron microscope 1 to move the workpiece stage 31 of the scanning electron microscope 1, which supports the inspection-target workpiece, in the X direction by the determined X-direction correction amount and in the Y direction by the determined Y-direction correction amount, thereby correcting the position of the workpiece stage 31. There may be cases where either the X-direction correction amount or the Y-direction correction amount is zero.

In step 405, the processing system 5 instructs the scanning electron microscope 1 to generate an image of the target inspection area on the inspection-target workpiece on the workpiece stage 31 whose position has been corrected.

In step 406, the processing system 5 performs the pattern matching between the pattern on the image of the target inspection area and the corresponding CAD pattern.

According to this embodiment, the position of the workpiece stage 31 is corrected based on the pattern density, so that the image shift of the target inspection area itself is reduced. As a result, accuracy of the pattern matching is improved, and the pattern matching is performed with a minimum search time.

The embodiments described with reference to the flowcharts of FIGS. 6 and 7 may be combined with the embodiments described with reference to the flowcharts of FIGS. 8 and 9. Specifically, both the matching-search distance and the position of the workpiece stage 31 may be corrected according to the pattern density of the target inspection area.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a technique for reducing an effect of image shift caused by charging of a surface of a workpiece on pattern matching.

### REFERENCE SIGNS LIST

1 Scanning electron microscope
5 Processing system
15 Electron gun
16 Converging lens
17 X deflector
18 Y deflector
20 Objective lens
26 Electron detector
28 Image acquisition device
31 Workpiece stage
35 Stage-moving device

1. A pattern matching method comprising:
setting a plurality of inspection areas in a patterned surface of a workpiece;
calculating pattern densities in the plurality of inspection areas from design data of patterns of the workpiece;
dividing the pattern densities into a plurality of density groups according to numerical values of the pattern densities;
generating images of the plurality of inspection areas by a scanning electron microscope;
performing pattern matching between a pattern on each of the images and a corresponding CAD pattern;
calculating a plurality of image shift amounts corresponding to the plurality of inspection areas based on results of the pattern matching;
dividing the plurality of inspection areas into a plurality of area groups corresponding to the plurality of density groups;
calculating a plurality of correction amounts corresponding to the plurality of area groups based on the image shift amounts corresponding to the inspection areas belonging to the respective area groups; and
generating correlation data indicating correlation between the plurality of density groups and the plurality of correction amounts.

2. The pattern matching method according to claim 1, further comprising:
calculating a pattern density of a target inspection area on an inspection-target workpiece from design data of pattern in the target inspection area, the inspection-target workpiece having a patterned surface of the same structure as the patterned surface of the workpiece;
selecting a density group to which the pattern density of the target inspection area belongs from the plurality of density groups;
correcting a matching-search distance using a correction amount corresponding to the selected density group;
generating an image of the target inspection area by scanning electron microscope; and
performing pattern matching between a pattern on the image of the target inspection area and a corresponding CAD pattern using the corrected matching-search distance.

3. The pattern matching method according to claim 2, wherein correcting the matching-search distance comprises correcting the matching-search distance by adding a correction amount corresponding to the selected density group to a reference search distance.

4. The pattern matching method according to claim 1, wherein calculating the plurality of correction amounts corresponding to the plurality of area groups comprises:
calculating an average and 3σ of image shift amounts corresponding to inspection area belonging to each of the area groups; and
calculating a correction amount that is the sum of the average and the 3σ for each of the area groups, thereby determining the plurality of correction amounts corresponding to the plurality of area groups.

5. A pattern matching method comprising:
setting a plurality of inspection areas in a patterned surface of a workpiece;
calculating pattern densities in the plurality of inspection areas from design data of patterns of the workpiece;
dividing the pattern densities into a plurality of density groups according to numerical values of the pattern densities;
generating images of the plurality of inspection areas by a scanning electron microscope;
performing pattern matching between a pattern on each of the images and a corresponding CAD pattern;
calculating a plurality of X-direction image shift amounts and a plurality of Y-direction image shift amounts corresponding to the plurality of inspection areas based on results of the pattern matching;
dividing the plurality of inspection areas into a plurality of area groups corresponding to the plurality of density groups;
calculating a plurality of X-direction correction amounts corresponding to the plurality of area groups based on the plurality of X-direction image shift amounts corresponding to the inspection areas belonging to the respective area groups;
calculating a plurality of Y-direction correction amounts corresponding to the plurality of area groups based on the plurality of Y-direction image shift amounts corresponding to the inspection areas belonging to the respective area groups;
generating X-direction correlation data indicating correlation between the plurality of density groups and the plurality of X-direction correction amounts; and
generating Y-direction correlation data indicating correlation between the plurality of density groups and the plurality of Y-direction correction amounts.

6. The pattern matching method according to claim 5, further comprising:
calculating a pattern density of a target inspection area on an inspection-target workpiece from design data of pattern in the target inspection area, the inspection-target workpiece having a patterned surface of the same structure as the patterned surface of the workpiece;
selecting a density group to which the pattern density of the target inspection area belongs from the plurality of density groups;
determining a X-direction correction amount and a Y-direction correction amount corresponding to the selected density group;
correcting a position of a workpiece stage of scanning electron microscope by moving the workpiece stage by the determined X-direction correction amount in an X direction and moving the workpiece stage by the determined Y-direction correction amount in a Y direction, the inspection-target workpiece being supported on the workpiece stage;
generating an image of the target inspection area of the inspection-target workpiece on the workpiece stage by the scanning electron microscope; and
performing pattern matching between a pattern on the image of the target inspection area and a corresponding CAD pattern.

7. The pattern matching method according to claim 5, wherein calculating the plurality of X-direction correction amounts corresponding to the plurality of area groups comprises:
calculating an average and 3σ of X-direction image shift amounts corresponding to inspection area belonging to each of the area groups; and
calculating an X-direction correction amount that is the sum of the average and the 3σ of the X-direction image shift amounts for each of the area groups, thereby determining the plurality of X-direction correction amounts corresponding to the plurality of area groups.

8. The pattern matching method according to claim 5, wherein calculating the plurality of Y-direction correction amounts corresponding to the plurality of area groups comprises:
calculating an average and 3σ of Y-direction image shift amounts corresponding to inspection area belonging to each of the area groups; and
calculating a Y-direction correction amount that is the sum of the average and the 3σ of the Y-direction image shift amounts for each of the area groups, thereby determining the plurality of Y-direction correction amounts corresponding to the plurality of area groups.
